(19) United States
(12) Patent Application Publication
(10) Pub. No.: US 2023/0317980 A1
(43) Pub. Date: Oct. 5, 2023

(54) ENERGY RECOVERY SYSTEM FOR FUEL CELL VEHICLE

(71) Applicant: ISUZU MOTORS LIMITED, Kanagawa (JP)

(72) Inventor: Makoto ABE, Fujisawa-shi (JP)

(21) Appl. No.: 18/186,337

(22) Filed: Mar. 20, 2023

(30) Foreign Application Priority Data
Mar. 22, 2022 (JP) 2022-046001

(51) Int. Cl. H01M 8/04029; B60K 11/02; H01M 8/04007; H10N 10/13

(52) U.S. Cl. CPC H01M 8/04029; B60K 11/02; H01M 8/04067; H10N 10/13; B60L 50/70

(57) ABSTRACT

An energy recovery system includes the following: a first cooling water circulation path for allowing circulation of first cooling water to supply the first cooling water to a fuel cell; a first radiator that cools the first cooling water heated by the fuel cell, and is provided in the first cooling water circulation path; and a first thermoelectric converter that converts heat radiated from the first radiator into electricity, and is provided in the first radiator.

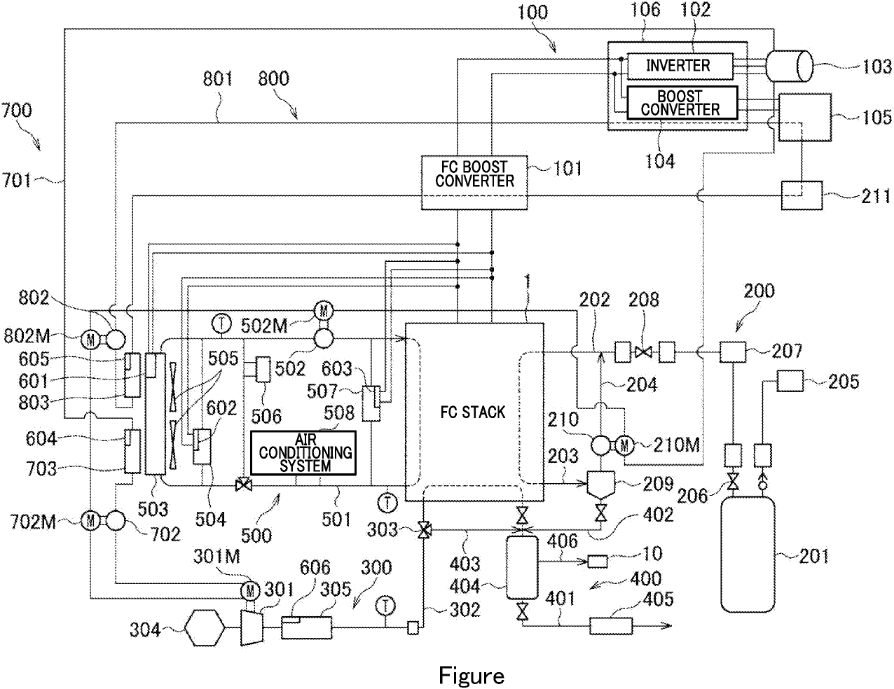

### CROSS REFERENCE TO RELATED APPLICATIONS

This application is entitled to the benefit of Japanese Patent Application No.2022-046001, filed on Mar. 22, 2022, the disclosure of which including the specification, drawings and abstract is incorporated herein by reference in its entirety.

### TECHNICAL FIELD

The present disclosure relates to an energy recovery system for a fuel cell vehicle.

### BACKGROUND ART

Patent Literature (hereinafter, referred to as PTL) 1 discloses a vehicle including a fuel cell system (fuel cell vehicle). A fuel cell system includes a fuel cell that generates electricity by using an electrochemical reaction between hydrogen and oxygen (air).

A fuel cell system is provided with a cooling system that cools a fuel cell for adjusting an operating temperature to a suitable temperature for the electrochemical reaction. Such a cooling system is provided with a cooling water path that allows circulation of cooling water (heat medium) in the fuel cell, a water pump that circulates the cooling water, an electric motor that drives the water pump, and a radiator including a fan. Heat generated in the fuel cell is discharged outside the system by the radiator through the cooling water.

### CITATION LIST

### Patent Literature

PTL 1 Japanese Patent Application Laid-Open No. 2004-311348

### SUMMARY OF INVENTION

### Technical Problem

A fuel cell is required to have a heat dissipation performance several times higher than that of a gasoline engine or a diesel engine; therefore, a large amount of thermal energy is discharged from a fuel cell vehicle to the outside and wasted.

An object of the present disclosure is to provide an energy recovery system for a fuel cell vehicle capable of effectively recovering energy that would be wasted.

### Solution to Problem

In order to achieve the above object, a first aspect of the present disclosure is an energy recovery system for a fuel cell vehicle, and the energy recovery system includes: a first cooling water circulation path for allowing circulation of first cooling water to supply the first cooling water to a fuel cell; a first radiator that cools the first cooling water heated by the fuel cell, the first radiator being provided in the first cooling water circulation path; and a first thermoelectric converter that converts heat radiated from the first radiator into electricity, the first thermoelectric converter being provided in the first radiator.

A second aspect of the present disclosure is the energy recovery system according to the first aspect, and the energy recovery system further includes: a first cooling water pump that circulates the first cooling water to supply the first cooling water to the fuel cell, the first cooling water pump being provided in the first cooling water circulation path; a first cooling water pump drive motor that drives the first cooling water pump; a second cooling water circulation path for allowing circulation of second cooling water to supply the second cooling water to the first cooling water pump drive motor; a second radiator that cools the second cooling water heated by the first cooling water pump drive motor, the second radiator being provided in the second cooling water circulation path; and a second thermoelectric converter that converts heat radiated from the second radiator into electricity, the second thermoelectric converter being provided in the second radiator..

A third aspect of the present disclosure is the energy recovery system according to the first aspect, and the energy recovery system further includes: a second cooling water pump that circulates the second cooling water to supply the second cooling water to the first cooling water pump drive motor, the second cooling water pump being provided in the second cooling water circulation path; and a second cooling water pump drive motor that drives the second cooling water pump, in which the second cooling water circulation path passes through the second cooling water pump drive motor.

A fourth aspect of the present disclosure is the energy recovery system according to any one of the first to third aspects, and the energy recovery system further includes: an exhaust gas supply path for supplying compressed exhaust gas discharged from the fuel cell to an air brake of the fuel cell vehicle.

### Advantageous Effects of Invention

An energy recovery system of the present disclosure can effectively recover energy that would be wasted by a fuel cell vehicle.

### BRIEF DESCRIPTION OF DRAWINGS

The FIGURE is a block diagram illustrating a fuel cell system including an energy recovery system according to an embodiment of the present disclosure.

### DESCRIPTION OF EMBODIMENTS

Hereinafter, an embodiment of the present disclosure will be described with reference to the drawings. An energy recovery system of the present embodiment is provided in a vehicle (fuel cell vehicle) including a fuel cell system.

### Schematic Configuration of Fuel Cell System

As illustrated in the FIGURE, the fuel cell system includes fuel cell (FC stack) 1, load circuit 100, hydrogen supply circuit 200, air supply circuit 300, exhaust gas circuit 400, and FC cooling circuit (first cooling circuit) 500. Fuel cell 1 generates electricity by using an electrochemical reaction between hydrogen and oxygen.

Load circuit 100 includes fuel cell boost converter 101, inverter 102, main drive motor 103, boost converter 104, and secondary cell 105. Inverter 102 and boost converter 104 form power control unit 106.

Fuel cell boost converter 101 boosts the voltage generated by fuel cell 1 to a voltage capable of driving main drive motor 103. Inverter 102 converts the boosted DC voltage into AC voltage and supplies the voltage to main drive motor 103. Main drive motor 103 drives the fuel cell vehicle and also functions as a regenerative motor during deceleration of the fuel cell vehicle. Boost converter 104 converts the voltage of fuel cell 1 and supplies the voltage to secondary cell 105, or converts the voltage of secondary cell 105 and supplies the voltage to inverter 102. Secondary cell 105 is charged with the electric power from fuel cell 1 and the electric power obtained by the regeneration performed by main drive motor 103, and also functions as a power source for driving main drive motor 103 and auxiliary equipment. Examples of the auxiliary equipment include drive motors (except main drive motor 103) respectively disposed in parts of the fuel cell system, inverters for driving the drive motors, and various types of other vehicle-mounted auxiliary equipment.

Hydrogen supply circuit 200 includes hydrogen tank 201, hydrogen supply path 202, hydrogen exhaust path 203, hydrogen reflux path 204, and hydrogen pump 210. Hydrogen tank 201 stores hydrogen gas supplied from filling port 205. Hydrogen supply path 202 connects hydrogen tank 201 with fuel cell 1. Hydrogen supply path 202 is provided with main stop valve 206, regulator 207, and injector 208 in this order from the hydrogen tank 201 side. Main stop valve 206 turns on and off the supply of hydrogen gas from hydrogen tank 201. Regulator 207 adjusts the pressure of hydrogen gas supplied to fuel cell 1. Injector 208 injects and supplies hydrogen gas to fuel cell 1.

Fuel exhaust gas from fuel cell 1 is discharged from hydrogen exhaust path 203. The fuel exhaust gas contains unreacted hydrogen gas, steam or water, nitrogen, and oxygen. Hydrogen reflux path 204 connects hydrogen exhaust path 203 with hydrogen supply path 202. Gas-liquid separator 209 is provided between hydrogen exhaust path 203 and hydrogen reflux path 204. Gas-liquid separator 209 separates water in the fuel exhaust gas from gases (impurities such as hydrogen and nitrogen). Hydrogen reflux path 204 is provided with hydrogen pump 210, which supplies the hydrogen gas separated by gas-liquid separator 209 to hydrogen supply path 202. In other words, the fuel cell system uses unreacted hydrogen gas contained in fuel exhaust gas as fuel. Hydrogen filling ECU 211 controls components such as main stop valve 206, regulator 207, injector 208, and drive motor 210M of hydrogen pump 210.

Air supply circuit 300 includes air compressor 301 and air supply path 302. Air compressor 301 compresses air and sends the air to fuel cell 1 via air supply path 302. Three-way valve 303 is provided in air supply path 302 at the inlet to fuel cell 1, and air flow meter 304 for measuring the intake amount of air is provided upstream of air compressor 301. Intercooler 305 for cooling air flowing through air supply path 300 is provided at air supply path 302 in a portion located between air compressor 301 and three-way valve 303.

Exhaust gas circuit 400 includes exhaust gas path 401, fuel gas discharge path 402, and air bypass path 403. Compressed exhaust gas discharged from fuel cell 1 flows into exhaust gas path 401. Exhaust gas path 401 is provided with buffer tank 404 for storing the exhaust gas. Fuel gas discharge path 402 connects exhaust gas path 401 with gas-liquid separator 209 upstream of buffer tank 404. Water and gas accumulated in gas-liquid separator 209 flow into exhaust gas path 401 via fuel gas discharge path 402. Air bypass path 403 connects exhaust gas path 401 with three-way valve 303 (at the inlet of air supply path 302) upstream of buffer tank 404. The downstream portion in exhaust gas path 401 is provided with silencer 405 for reducing exhaust noise.

FC cooling circuit 500 includes FC cooling water circulation path (first cooling water circulation path) 501, FC cooling water pump (first cooling water pump) 502, FC main radiator (first radiator) 503, and FC sub radiator 504. FC cooling water circulation path 501 is a pipe that allows circulation of cooling water (first cooling water) therein to supply the cooling water to fuel cell 1. FC cooling water circulation path 501 is provided with FC cooling water pump 502, which circulates the cooling water in FC cooling circuit 500 to supply the cooling water to fuel cell 1. FC main radiator 503 is provided in a portion-outside fuel cell 1—of FC cooling water circulation path 501. FC main radiator 503 cools the cooling water heated by fuel cell 1. Radiator fans 505 are provided in the vicinity of FC main radiator 503. Radiator fan 505 sends air to FC main radiator 503 to promote heat dissipation from FC main radiator 503. FC cooling water circulation path 501 is provided with FC sub radiator 504, which is in parallel with FC main radiator 503. FC sub radiator 504 supplements the cooling of the cooling water by FC main radiator 503. At FC cooling water circulation path 501, ion exchanger 506 for maintaining insulation of the cooling water and intercooler 507 for cooling the cooling water are disposed in parallel with FC main radiator 503 and FC sub radiator 504. The cooling water heated by fuel cell 1 is used for heating the interior of the vehicle by air conditioning system 508.

### Energy Recovery From FC Cooling Circuit

In FC cooling circuit 500, FC main radiator 503, FC sub radiator 504, and intercooler 507 are provided with thermoelectric converters 601, 602, and 603, respectively. Thermoelectric converters 601, 602, and 603 are each include a thermoelectric conversion element. Thermoelectric converters 601, 602, 603 convert the exhaust heat radiated from FC main radiator 503, FC sub radiator 504, and intercooler 507 into electricity, and supply the electricity to load circuit 100 in a portion located between fuel cell 1 and fuel cell boost converter 101. This configuration enables effective use of the heat generated by FC cooling circuit 500 for driving main drive motor 103 and/or charging secondary cell 105.

### Energy Recovery From Motor

The fuel cell system of the present embodiment is provided with motor cooling circuit (second cooling circuit) 700.

Motor cooling circuit 700 includes motor cooling water circulation path (second cooling water circulation path) 701, motor cooling water pump (second cooling water pump) 702, and motor cooling radiator (second radiator) 703. Motor cooling water circulation path 701 is a pipe that allows circulation of cooling water (second cooling water) therein to supply the cooling water to main drive motor 103, drive motor 210M for hydrogen pump 210, drive motor 502M for FC cooling water pump 502 (first cooling water pump drive motor 502M for driving the first cooling water pump), drive motor 802M for board cooling water pump 802 (described below), drive motor 702M for motor cooling water pump 702 (second cooling water pump drive motor 702M for driving the second cooling water pump), and drive motor 301M for air compressor 301, thereby cooling the motors. Motor cooling water circulation path 701 passes through these motors 103, 210M, 502M, 802M, 702M, and 301M. Motor cooling water circulation path 701 is provided with motor cooling water pump 702, which circulates the cooling water in motor cooling circuit 700 to supply the cooling water to motors 103, 210M, 502M, 802M, 702M, and 301M. Motor cooling water circulation path 701 is provided with motor cooling radiator 703, which cools the cooling water heated by motors 103, 210M, 502M, 802M, 702M, and 301M.

Motor cooling radiator 703 is provided with thermoelectric converter 604. Thermoelectric converter 604 includes a thermoelectric conversion element. Thermoelectric converter 604 converts the exhaust heat radiated from motor cooling radiator 703 into electricity, and supply the electricity to load circuit 100 in the portion located between fuel cell 1 and fuel cell boost converter 101. This configuration enables effective use of the heat generated by motors 103, 210M, 502M, 802M, 702M, and 301M for driving main drive motor 103 and/or charging secondary cell 105.

### Energy Recovery From Electric Board

The fuel cell system of the present embodiment is provided with board cooling circuit 800.

Board cooling circuit 800 includes board cooling water circulation path 801, board cooling water pump 802, and board cooling radiator 803. Board cooling water circulation path 801 is a pipe that allows circulation of cooling water therein to supply the cooling water to fuel cell boost converter 101, hydrogen filling ECU 211, secondary cell 105, and power control unit 106, thereby cooling, for example, the electric boards of these electric devices. Board cooling water circulation path 801 passes through these electric devices. Board cooling water circulation path 801 is provided with board cooling water pump 802, which circulates the cooling water in board cooling circuit 800 to supply the cooling water to the electric devices. Board cooling water circulation path 801 is provided with board cooling radiator 803, which cools the cooling water heated by the electric devices.

Board cooling radiator 803 is provided with thermoelectric converter 605. Thermoelectric converter 605 includes a thermoelectric conversion element. Thermoelectric converter 605 converts the exhaust heat radiated from board cooling radiator 803 into electricity, and supply the electricity to load circuit 100 in the portion located between fuel cell 1 and fuel cell boost converter 101. This configuration enables effective use of the heat generated by the electric devices for driving main drive motor 103 and charging secondary cell 105.

### Energy Recovery From Air Supply Circuit

Intercooler 305 of air supply circuit 300 is provided with thermoelectric converter 606. Thermoelectric converter 606 includes a thermoelectric conversion element. Thermoelectric converter 606 converts the exhaust heat generated in intercooler 305 into electricity, and supply the electricity to load circuit 100 in the portion located between fuel cell 1 and fuel cell boost converter 101. This configuration enables effective use of the heat generated by intercooler 305 for driving main drive motor 103 and charging secondary cell 105.

### Effective Use of Compressed Air

The fuel cell system of the present embodiment includes buffer tank 404 for storing compressed exhaust gas discharged from fuel cell 1, and exhaust gas supply path 406 for supplying the compressed exhaust gas stored in buffer tank 404 to air brake 10 of the fuel cell vehicle. This configuration enables effective use of the compressed exhaust gas discharged from fuel cell 1 for operating air brake 10.

While the present disclosure has been described based on the above embodiment, the present invention is not limited to the contents of the above embodiment, and can be appropriately modified within the scope of the present invention. In other words, all other embodiments, examples, operation techniques, and the like made by a person skilled in the art based on the present embodiment are included in the scope of the present invention.

For example, radiators 503, 504, 703, and 803 and intercoolers 305 and 507 are respectively provided with thermoelectric converters 601 to 606 in the above embodiment; however, a radiator with a thermoelectric conversion function or an intercooler with a thermoelectric conversion function may be used in place of each converter.

### INDUSTRIAL APPLICABILITY

The present invention is applicable to various fuel cell vehicles.

What is claimed is:

1. An energy recovery system for a fuel cell vehicle, the energy recovery system comprising:
a first cooling water circulation path for allowing circulation of first cooling water to supply the first cooling water to a fuel cell;
a first radiator that cools the first cooling water heated by the fuel cell, the first radiator being provided in the first cooling water circulation path; and
a first thermoelectric converter that converts heat radiated from the first radiator into electricity, the first thermoelectric converter being provided in the first radiator.

2. The energy recovery system according to claim 1, further comprising:
a first cooling water pump that circulates the first cooling water to supply the first cooling water to the fuel cell, the first cooling water pump being provided in the first cooling water circulation path;
a first cooling water pump drive motor that drives the first cooling water pump;
a second cooling water circulation path for allowing circulation of second cooling water to supply the second cooling water to the first cooling water pump drive motor;
a second radiator that cools the second cooling water heated by the first cooling water pump drive motor, the second radiator being provided in the second cooling water circulation path; and
a second thermoelectric converter that converts heat radiated from the second radiator into electricity, the second thermoelectric converter being provided in the second radiator.

3. The energy recovery system according to claim 2, further comprising:
a second cooling water pump that circulates the second cooling water to supply the second cooling water to the first cooling water pump drive motor, the second cooling water pump being provided in the second cooling water circulation path; and
a second cooling water pump drive motor that drives the second cooling water pump, wherein
the second cooling water circulation path passes through the second cooling water pump drive motor.

4. The energy recovery system according to claim 1, further comprising:
an exhaust gas supply path for supplying compressed exhaust gas discharged from the fuel cell to an air brake of the fuel cell vehicle.
